(19) United States
(12) Patent Application Publication
(10) Pub. No.: US 2023/0131741 A1
(43) Pub. Date: Apr. 27, 2023

(54) SYSTEMS AND METHODS FOR PREFERENCE ELICITATION ON CAR DESIGNS

(71) Applicant: Toyota Research Institute, Inc., Los Altos, CA (US)

(72) Inventors: Jonathan A. DeCastro, Arlington, MA (US); Shabnam Hakimi, Chapel Hill, NC (US); Emily Sumner, Berkeley, CA (US); Yue Weng, San Mateo, CA (US); Nikos Arechiga, San Mateo, CA (US)

(73) Assignee: Toyota Research Institute, Inc., Los Altos, CA (US)

(21) Appl. No.: 17/508,110

(22) Filed: Oct. 22, 2021

(51) Int. Cl. G06Q 30/02; G06F 30/27; G06F 30/12

(52) U.S. Cl. CPC G06Q 30/0282; G06F 30/27; G06F 30/12; G06Q 30/0201

(57) ABSTRACT

Systems and methods for providing a design with consumer feedback are provided. The method may include receiving a design within a design environment, wherein the design comprises a plurality of attributes. The method may further include automatically generating, using a computer model, consumer-based feedback regarding at least one attribute of the plurality of attributes. The method may additionally include presenting the consumer-based feedback within the design environment in real-time.

### TECHNICAL FIELD

Embodiments described herein generally relate to product design and, more particularly, a tool to validate rather than prescribe designs.

### BACKGROUND

Traditionally, product design has been based on limited information provided to the designer, and is often top-down, i.e., they are given design specifications and allowed to design within them. Product designers and marketers are rarely cognizant of the bigger picture of what specific types of consumers would prefer, and thus have certain blind spots in their ability to construct a product that meets consumer needs. As a result, some product ideas are not tightly coupled to consumer preferences and some design teams make decisions absent information on a consumer's preference.

### SUMMARY

Embodiments described herein generally relate tools to validate rather than prescribe designs. Embodiments relate to having the designer input a design idea and analyze the design against the specified consumer preferences to determine whether the design is consistent with consumer demands. Embodiments also identify common design deficiencies in a particular designer's work as it relates to customer preferences by using a combination of tools from cognitive science and machine learning.

In one embodiment, a system for providing a design with consumer feedback may include one or more processors and a non-transitory, computer-readable medium storing instructions that, when executed by the one or more processors, causes the one or more processors to receive a design within a design environment, wherein the design comprises a plurality of attributes. The instructions may further cause the one or more processors to automatically generate, using a computer model, consumer-based feedback regarding at least one attribute of the plurality of attributes. The instructions may additionally cause the one or more processors to present the consumer-based feedback within the design environment in real-time.

In another embodiment, a method may include receiving a design within a design environment, wherein the design comprises a plurality of attributes. The method may further include automatically generating, using a computer model, consumer-based feedback regarding at least one attribute of the plurality of attributes. The method may additionally include presenting the consumer-based feedback within the design environment in real-time.

These and additional features provided by the embodiments described herein will be more fully understood in view of the following detailed description, in conjunction with the drawings.

### BRIEF DESCRIPTION OF THE DRAWINGS

The embodiments set forth in the drawings are illustrative and exemplary in nature and not intended to limit the subject matter defined by the claims. The following detailed description of the illustrative embodiments can be understood when read in conjunction with the following drawings, where like structure is indicated with like reference numerals and in which:

FIG. 1A schematically depicts a designer creating a design, according to one or more embodiments described and illustrated herein;

FIG. 1B schematically depicts design query crowd-sourcing among consumers by the user depicted by FIG. 1A, according to one or more embodiments described and illustrated herein;

FIG. 2 schematically depicts a consumer-in-the-loop approach flowchart for validating a design according to elicited preferences, according to one or more embodiments described and illustrated herein;

FIG. 3 schematically depicts a model-in-the-loop approach flowchart for validating a design according to elicited preferences, according to one or more embodiments described and illustrated herein;

FIG. 4 schematically depicts a model training process flowchart used to train the model depicted in FIGS. 2 and 3, according to one or more embodiments described and illustrated herein; and

FIG. 5 is a block diagram illustrating computing hardware utilized in one or more devices for implementing various processes and systems, according one or more embodiments described and illustrated herein.

### DETAILED DESCRIPTION

Product designers often take multiple factors into consideration when designing a new product, such as a vehicle component. Considerations such as functionality, aesthetic appeal, interoperability, and cost can factor into, for example, which components are ultimately utilized in a vehicle. However, this approach can ignore designs that consumers actually want, and wind up introducing a design that is unpopular with a segment/demographic in the market that is important.

By contrast, taking a more consumer-centric approach before a final design is chosen can result in greater consumer satisfaction with the item under design. This advantageous approach can be implemented in the form of a tool to validate designs, rather than one to prescribe designs. This can not only help designers create designs more in accordance with consumer preferences, but also help designers identify areas of design where they lack the information to create a design in accordance with available consumer data. This, in turn, produces a real-world benefit of encouraging design decisions based on important goals such as meeting consumer needs, streamlining the decision-making and acceptance process, and avoiding pitfalls of errant design decisions.

Embodiments of the present disclosure are directed to systems and methods for preference elicitation on car designs. Particularly, this can be realized using a combination of tools from cognitive science and machine learning, and utilizing generative models that predict outputs based on a previous set of inputs and outputs. Such models can also be reward-based models, which predict an output based on the likelihood of receiving positive reward. In this case, the reward may be approval from the designer or user. Each of these models may provide the necessary generality to cover the behavior or preferences of individuals or entire market segments. For instance, one can draw from reward structures or generative models to effectively learn preferences with varying, desired degrees of specificity or generality. This may draw data from consumers to generate a model of consumer preferences. The model is more precise in areas where there is more consumer data and less precise in areas lacking data to accurately predict consumer preferences. To elicit preferences, the system can generate queries based on those data gaps in the learned model, as well as queries provided by the designer/user and active learning.

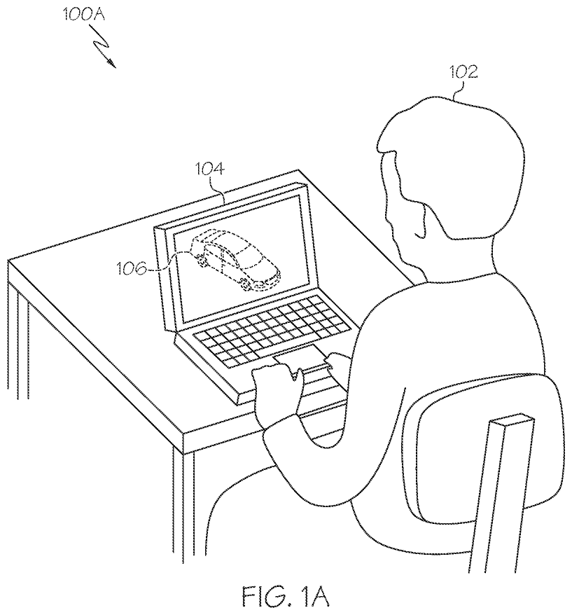

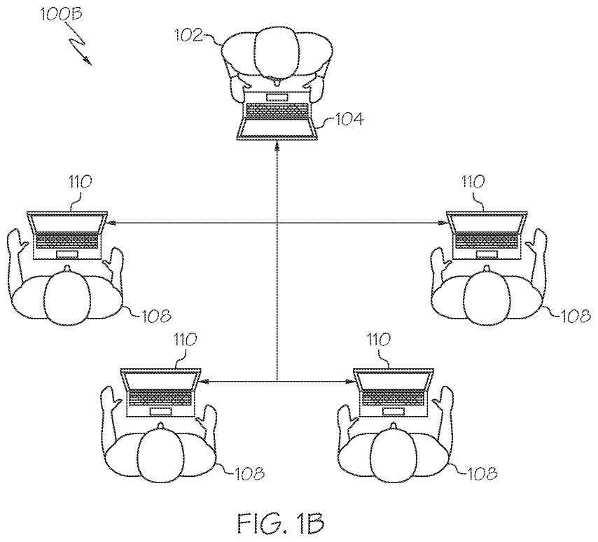

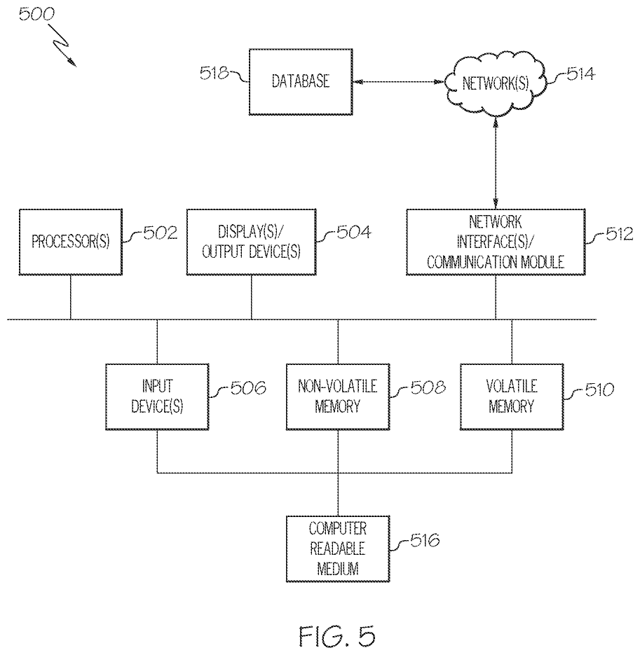

Referring now to FIG. 1A, an example of a user 102 creating a design 106 is schematically illustrated in a perspective view 100A. A user 102 may be, by way of non-limiting example, a designer (graphic designer, engineer, artist, marketer, and the like) and/or any other person capable of creating or updating a design 106. A design 106 may be any suitable representation of an object capable of being displayed, created, and/or edited on a user computer 104, such as computer-aided design (CAD) and the like. Designs for any suitable objects (automobile components and the like) may be utilized. A user computer 104 may be any suitable device capable allowing a user 102 to work with a design 106, such as by way of non-limiting example a desktop, laptop, smartphone, tablet, server, personal digital assistant, wearable computing device, and like. Further examples of computers, such as a user computer 104, are discussed in more detail with respect to FIG. 5.

Referring now to FIG. 1B, an example of design query crowd-sourcing among consumers by the user depicted by FIG. 1A is schematically illustrated in an overhead view 100B. The user 102 utilizing their user computer 104 is depicted as being in communication with multiple consumers 108, each using a corresponding consumer computer 110. A consumer 108 may include any person capable of using a computing device to view, evaluate, and/or provide other feedback regarding a design. A consumer computer 110 may be any suitable device capable allowing a consumer to view, evaluate, and/or provide other feedback regarding a particular design, such as by way of non-limiting example a desktop, laptop, smartphone, tablet, server, personal digital assistant, wearable computing device, and like. Further examples of computers, such as a consumer computer 110, are discussed in more detail with respect to FIG. 5.

Any suitable number of users 102, user computers 104, consumers 108, and consumer computers 110 may be utilized in any suitable configuration. Each consumer 108 may view and provide feedback regarding a design put forth by the user 102. In this embodiment, the user 102 and each consumer 108 are located remotely from each other such that each user computer 104 and consumer computer 110 communicates over a network, as further discussed herein with respect to FIG. 5. Any suitable configuration for communication (local, remote, wired, wireless, and the like) may be utilized to facilitate communication between user computer(s) 104 and/or consumer computer(s) 110.

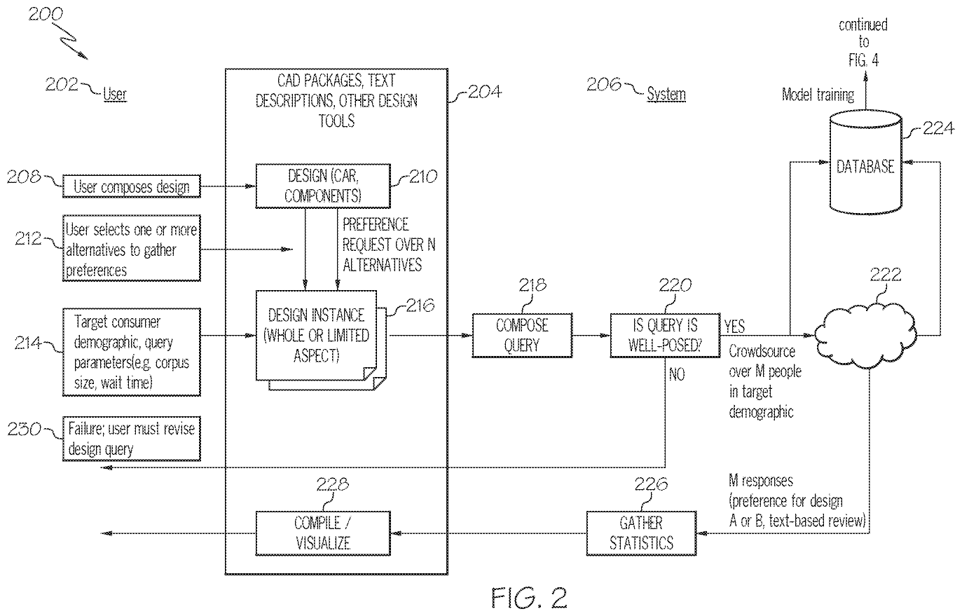

Referring now to FIG. 2, an exemplary consumer-in-the-loop approach flowchart 200 for validating a design according to elicited preferences is schematically depicted. In this embodiment, a user 202 utilizes one or more design tools 204 to pose a design query a system 206. The user 202 may correspond to the user 102 depicted in FIGS. 1A-B. The design tools 204 may be utilized to create and/or modify the design 106 depicted in FIG. 1A, and may utilize any suitable tools or data to create designs, such as CAD packages, textual descriptions, and the like. The system 206 may utilize any suitable computing configuration, including by way of non-limiting example, one or more servers, a cloud implementation 222, one or more databases 224, and/or any other suitable computing and/or networking components.

At block 208, the user 202 may compose and/or select a design. As discussed with regards to the design 106 in FIG. 1A, a design may be for any type of object or component thereof. By way of non-limiting examples, an object may be an automobile, and a component may be a brake pedal in the automobile. At block 210, a subject design may be created within the design tools 204. For example, the user 202 may create a subject design of a brake pedal in CAD or any other suitable design tool, provide a textual description of the design, and the like.

At block 212, the user 202 may select or create one or more alternative designs to gather preferences. By way of non-limiting example, if the brake pedal in the subject design is rectangular, an alternative design may be an oval-shaped brake pedal. In some embodiments, the user 202 may create one or more alternative designs. In other embodiments, the user 202 may select (rather than create) alternative designs, such that the user may be provided one or more potential alternative designs to choose from when selecting an alternative design. In other embodiments, a user 202 may be able to create one or more alternative designs as well as select another alternative design from among one or more alternative designs from which to choose.

At block 214, a target demographic and/or design query parameters may be entered. A target demographic of consumers be based upon one or more of any suitable criteria (age, gender, income, nationality, locality, income, occupation, type of vehicle owned, and the like). Design query parameters may include, by way of non-limiting example, corpus size (i.e., the total number of consumers from which to form a target demographic) and wait time (i.e., an amount of time until a consumer must provide a design query response to select a design). At block 216, a design instance may be created by implementing the subject design created by the user 202, along with a quantity N of alternative designs, and the target consumer demographic and design query parameters. The design instance may relate to the entirety of a design (e.g., an entire brake pedal) or certain aspects (e.g., brake pedal shape, material, color, and the like). Continuing with the brake pedal example, a design instance may include a subject design of a brake pedal, one or more alternative designs,

At block 218, a design query is composed by the system 206 based upon the subject model, one or more alternative models, target consumer demographic in formation, and the design query parameters. At block 220, a determination may be made regarding whether the design query is well-posed. In this embodiment, a design query is well-posed if it satisfies one or more suitable criteria as would readily be known to one of ordinary skill in the art. As a non-limiting example, a point-biserial analysis can reveal whether one design poses a weak alternative(i.e., an outlier) to the subject design, and thus does not provide much insight of the target demographic in a choice between designs having more similar levels of appeal. For example, a useful range for alternative design consumer preference within a target demographic may be 20-30%. Thus, returning to the brake pedal example, an alternative brake pedal design utilizing a very heavy material may be far less preferable to a lighter material used in the material of the subject brake pedal design. Thus, if 95% of consumers in the target demographic prefer the subject design over the alternative design due to the heaviness of the brake pedal material in the second design, the alternative design may not have been well-posed to provide the user 202 with much useful insight into target demographic consumer preferences among viable/realistic options.

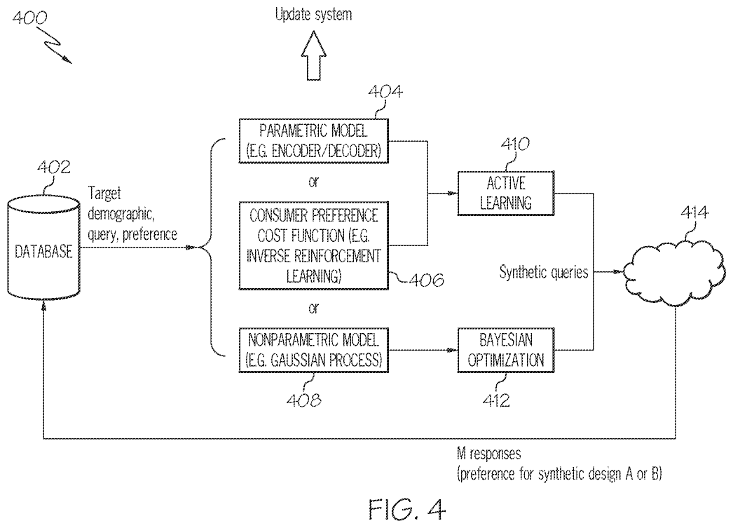

If the design query is not well-posed (“NO” at block 220), then at block 230 the design query may be rejected or otherwise fail, such that the user 202 then may then revise/update the design query back at block 208. Otherwise, if the design query is well-posed (“YES” at block 220), then the design query may be crowdsourced over a quantity (M) of people within the specified target demographic. In this embodiment, people within the specified target demographic may correspond to the consumers 108 depicted in FIG. 1B. The design query may be stored in a database 224, which, by way of non-limiting example may correspond to the database 518 discussed herein with respect to FIG. 5. The design query may also be crowdsourced in the cloud 222, such that the results may be stored in the database 224 along with the design query. In this way, the database 224 may be utilized for model training as discussed in more detail with respect to FIG. 4.

The crowdsourced M quantity of responses may be utilized to gather statistics at block 226. Continuing with the brake pedal example, statistics regarding the responses among consumers within the target demographic may be gathered, such as an analysis showing how many of the M consumers within the target demographic voted for each design, whether by singular choice voting or rank choice voting. At block 228, the statistics may be gathered and be visually or otherwise presented as part of the design tools 204 and/or the system 206. Any suitable representation of the statistics may be utilized, including but not limited to graphs, pie charts, textual descriptions, and the like.

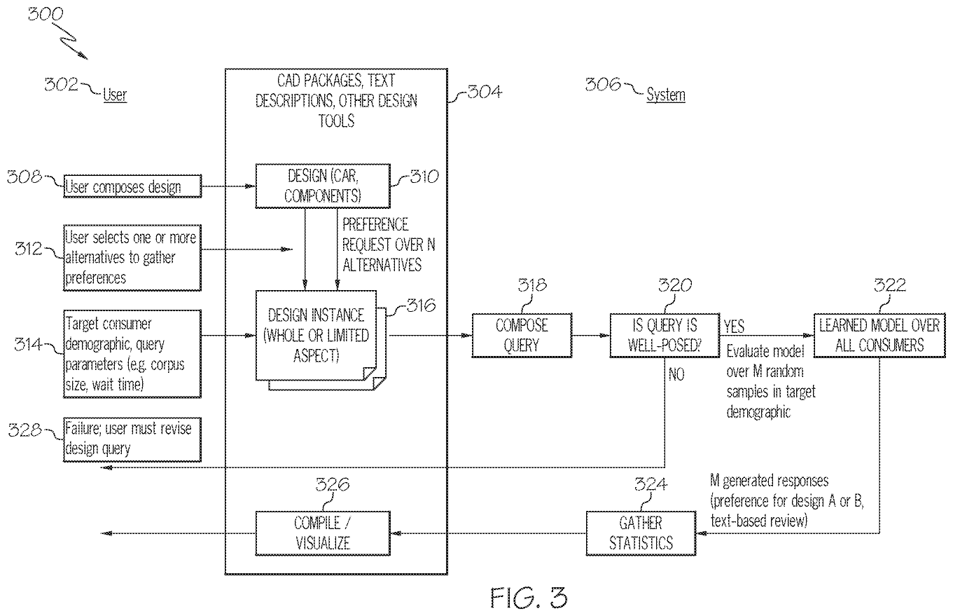

Referring now to FIG. 3, an exemplary model-in-the-loop approach flowchart 300 for validating a design according to elicited preferences is schematically depicted. In this embodiment, a user 302 utilizes one or more design tools 304 to pose a design query a system 306. The user 302 may correspond to the user 102 depicted in FIGS. 1A-B. The design tools 304 may be utilized to create and/or modify the design 106 depicted in FIG. 1A, and may utilize any suitable tools or data to create designs, such as CAD packages, textual descriptions, and the like. The system 306 may utilize any suitable computing configuration, including by way of non-limiting example, a computer learning model and/or any other suitable computing and/or networking components.

At block 208, the user 302 may compose and/or select a design. As discussed with regards to the design 106 in FIG. 1A, a design may be for any type of object or component thereof. By way of non-limiting examples, an object may be an automobile, and a component may be a brake pedal in the automobile. At block 310, a subject design may be created within the design tools 304. For example, the user 302 may create a subject design of a brake pedal in CAD or any other suitable design tool, provide a textual description of the design, and the like.

At block 312, the user 302 may select or create one or more alternative designs to gather preferences. By way of non-limiting example, if the brake pedal in the subject design is rectangular, an alternative design may be an oval-shaped brake pedal. In some embodiments, the user 302 may create one or more alternative designs. In other embodiments, the user 302 may select (rather than create) alternative designs, such that the user may be provided one or more potential alternative designs to choose from when selecting an alternative design. In other embodiments, a user 302 may be able to create one or more alternative designs as well as select another alternative design from among one or more alternative designs from which to choose.

At block 314, a target demographic and/or design query parameters may be entered. A target demographic of consumers be based upon one or more of any suitable criteria (age, gender, income, nationality, locality, income, occupation, type of vehicle owned, and the like). Design query parameters may include, by way of non-limiting example, corpus size (i.e., the total number of consumers from which to form a target demographic) and wait time (i.e., an amount of time until a consumer must provide a design query response to select a design). At block 316, a design instance may be created by implementing the subject design created by the user 302, along with a quantity N of alternative designs, and the target consumer demographic and design query parameters. The design instance may relate to the entirety of a design (e.g., an entire brake pedal) or certain aspects (e.g., brake pedal shape, material, color, and the like). Continuing with the brake pedal example, a design instance may include a subject design of a brake pedal, one or more alternative designs,

At block 318, a design query may be composed by the system 306 based upon the subject model, one or more alternative models, target consumer demographic in formation, and the design query parameters. At block 320, the system 306 may make a determination regarding whether the design query is well-posed. If the design query is not well-posed (“NO” at block 320), then at block 328 the design query is rejected or otherwise fails, such that the user 302 may then revise/update the design query at block 308. Otherwise, if the design query is well-posed (“YES” at block 320), then at block a learned model 322 may be used to provide data regarding predicted design preference within a target consumer demographic, such as where consumer preference data may be sparse with respect to a target demographic that has not been asked about a particular feature before. The trained or learned model 322 in this embodiment may, for example, be derived from a model previously trained in the model training process. In some embodiments, the learned model 322 may be updated, during or input between uses, via the exemplary model training process discussed herein regarding FIG. 4.

Referring now to FIG. 4, an exemplary model training process flowchart 400 used to receive data from the consumer-in-the-loop approach in FIG. 2 and to train the model depicted in FIG. 3 is schematically depicted. A database 402 may contain a design query, results associated with the design query, and/or crowdsourced preference data relating to responses of consumers within a target demographic in response to the design query. The database 402 may correspond to the databases 224 in FIG. 2 and/or 518 in FIG. 5. The design query, target demographic data, and/or preference data may be provided to one or more functions/models to train the system depicted as 206 in FIGS. 2 and 306 in FIG. 3.

The design query, target demographic data, and/or preference data may be provided from the database 402 to a parametric model 404, which may be implemented as an encoder/decoder. More specifically, this parametric model 404 approach may be used (for example) for CAD designs in a manner that discerns the user's design intent using features and constraints, as is known to one of ordinary skill in the art. The parametric model 404 allows users to automate repetitive/small,/incremental changes to the CAD design, such as those found in families of products. For example, a parametric model 404 may be utilized in the design of a brake pedal within a known family of related brake pedals.

Alternatively, the design query, target demographic data, and/or preference data may be provided from the database 402 to a consumer preference cost function 406. This may be implemented with an inverse reinforcement learning function, which may be utilized to incentivize a model by trial and error to naturally learn correct decisions and to pursue a long term reward, as is known to one of ordinary skill in the art.

As another alternative, the design query, target demographic data, and/or preference data may be provided from the database 402 to a nonparametric model 408, which may not conform to a normal distribution, and utilize continuous data rather than discrete values. The non-parametric model may utilize ordinal numbers or other relative data (i.e., data that does not have a value as a fixed discrete number). Thus, a parametric Gaussian process (PGP) may be utilized to encode large amounts of data into a small number of hypothetical data points, as is known to one of ordinary skill in the art. For example, where there are large amounts of consumer data regarding design models, hypothetical data points can be derived to make predictions regarding the outcome of a design query.

If the parametric model 404 or consumer preference cost function 406 are utilized to process the design query, target demographic data, and/or preference data, then active learning 410 may be utilized to generate synthetic design queries. The active learning 410 may utilize users interacting with low-confidence data to provide output back as input for the model, as is known to one of ordinary skill in the art. Alternatively, if the nonparametric model 408 is utilized to process the design query, target demographic data, and/or preference data, then Bayesian optimization 412 may be utilized to optimize the output of the nonparametric model 408 to generate synthetic design queries to the cloud 414. Bayesian optimization 412 may be used to optimize functions whose operating details are not completely known, as would be understood by one of ordinary skill in the art. For example, the performance of design queries may be modified by Bayesian optimization 412 based upon beliefs about the behavior the design queries.

Synthetic queries in this embodiment utilize data regarding previous data in the model regarding the design query, target demographic data, and/or preference data to self-generate design queries to be further evaluated. The synthetic queries may be run utilizing the cloud 414 to elicit crowdsourced preference data for one synthetic design over another. Specifically, M responses from M consumers in the target demographic may be utilized to determine a preference for one design over another. The cloud 414 implementation may correspond to the cloud depicted in 222 of FIG. 2 and/or the network(s) in 514 of FIG. 5.

Turning now to FIG. 5, a block diagram illustrates an exemplary computing device 500, through which embodiments of the disclosure can be implemented. The computing device 500 described herein is but one example of a suitable computing device and does not suggest any limitation on the scope of any embodiments presented. The computing device 500 in some embodiments may also be utilized to implement the designer computer 104, the consumer computers 110, the system 206 depicted in FIG. 2, the system 306 depicted in FIG. 3, and/or any combination thereof. Nothing illustrated or described with respect to the computing device 500 should be interpreted as being required or as creating any type of dependency with respect to any element or plurality of elements. In various embodiments, the computing device 500 may include, but need not be limited to, a desktop, laptop, server, client, tablet, smartphone, or any other type of device that can utilize data. In an embodiment, the computing device 500 includes at least one processor 502 and memory comprising non-volatile memory 508 and/or volatile memory 510. The computing device 500 can include one or more displays and/or output devices 504 such as, for example, monitors, speakers, headphones, projectors, wearable-displays, holographic displays, and/or printers. Output devices 504 may further include, for example, displays and/or speakers of the designer computer 104, the consumer computers 110, devices that emit energy (radio, microwave, infrared, visible light, ultraviolet, x-ray and gamma ray), electronic output devices (Wi-Fi, radar, laser, etc.), audio (of any frequency), and the like.

The computing device 500 may further include one or more input devices 506 which can include, by way of example, any type of mouse, keyboard, disk/media drive, memory stick/thumb-drive, memory card, pen, touch-input device, biometric scanner, voice/auditory input device, motion-detector, camera, scale, and any device capable of measuring data such as motion data (e.g., an accelerometer, GPS, a magnetometer, a gyroscope, etc.), biometric data blood pressure, pulse, heart rate, perspiration, temperature, voice, facial-recognition, motion/gesture tracking, gaze tracking, iris or other types of eye recognition, hand geometry, oxygen saturation, glucose level, fingerprint, DNA, dental records, weight, or any other suitable type of biometric data, etc.), video/still images, and audio (including human-audible and human-inaudible ultrasonic sound waves). Input devices 506 may include cameras (with or without audio recording), such as digital and/or analog cameras, still cameras, video cameras, thermal imaging cameras, infrared cameras, cameras with a charge-couple display, night-vision cameras, three-dimensional cameras, webcams, audio recorders, and the like.

The computing device 500 typically includes non-volatile memory 508 (e.g., ROM, flash memory, etc.), volatile memory 510 (e.g., RAM, etc.), or a combination thereof. A network interface 512 can facilitate communications over a network 514 with other data source such as a database 518 via wires, a wide area network, a local area network, a personal area network, a cellular network, a satellite network, and the like. Suitable local area networks may include wired Ethernet and/or wireless technologies such as, for example, wireless fidelity (Wi-Fi). Suitable personal area networks may include wireless technologies such as, for example, IrDA, Bluetooth, Wireless USB, Z-Wave, ZigBee, and/or other near field communication protocols. Suitable personal area networks may similarly include wired computer buses such as, for example, USB and FireWire. Suitable cellular networks may include, but are not limited to, technologies such as LTE, WiMAX, UMTS, CDMA, and GSM. Network interface 512 can be communicatively coupled to any device capable of transmitting and/or receiving data via one or more network(s) 514. Accordingly, the network interface 512 can include a communication transceiver for sending and/or receiving any wired or wireless communication. For example, the network interface 512 may include an antenna, a modem, LAN port, Wi-Fi card, WiMax card, mobile communications hardware, near-field communication hardware, satellite communication hardware and/or any wired or wireless hardware for communicating with other networks and/or devices.

A computer-readable medium 516 may comprise a plurality of computer readable mediums, each of which may be either a computer readable storage medium or a computer readable signal medium. A computer readable storage medium may reside, for example, within an input device 506, non-volatile memory 508, volatile memory 510, or any combination thereof. A computer readable storage medium can include tangible media that is able to store instructions associated with, or used by, a device or system. A computer readable storage medium includes, by way of example: RAM, ROM, cache, fiber optics, EPROM/Flash memory, CD/DVD/BD-ROM, hard disk drives, solid-state storage, optical or magnetic storage devices, diskettes, electrical connections having a wire, or any combination thereof. A computer readable storage medium may also include, for example, a system or device that is of a magnetic, optical, semiconductor, or electronic type. Computer readable storage media and computer readable signal media are mutually exclusive.

A computer readable signal medium can include any type of computer readable medium that is not a computer readable storage medium and may include, for example, propagated signals taking any number of forms such as optical, electromagnetic, or a combination thereof. A computer readable signal medium may include propagated data signals containing computer readable code, for example, within a carrier wave. Computer readable storage media and computer readable signal media are mutually exclusive.

The computing device 500 may include one or more network interfaces 512 to facilitate communication with one or more remote devices, which may include, for example, client and/or server devices. The network interface 512 may also be described as a communications module, as these terms may be used interchangeably. The database 518 is depicted as being accessible over the network 514 and may reside within a server, the cloud, or any other configuration to support being able to remotely access data and store data in the database 518.

It should now be understood that embodiments of the present disclosure are directed to systems and methods for providing a design with consumer feedback using consumer-in-the-loop approach or model-in-the-loop embodiments. A user may compose a design and provide alternative designs to give consumers within a target demographic a choice among the designs. In a consumer-in-the-loop embodiment, the design query may be crowdsourced over a quantity of consumers in a target demographic and the resulting data may be used to train the model. In the model-in-the-loop embodiment, the model may be learned over all consumers in a set. In either embodiment, statistics may be gathered pertaining to the generated responses for consumer design preference. In training the model, the computer model may be generated based upon a well-posed design query crowdsourced among a subset of people in a target demographic utilizing a parametric model, nonparametric model, or a consumer preference cost function. The computer model may be further generated by utilizing active learning to generate synthetic queries whose synthetic results are stored in a database and used to further train the model.

It is noted that recitations herein of a component of the present disclosure being “configured” or “programmed” in a particular way, to embody a particular property, or to function in a particular manner, are structural recitations, as opposed to recitations of intended use. More specifically, the references herein to the manner in which a component is “configured” or “programmed” denotes an existing physical condition of the component and, as such, is to be taken as a definite recitation of the structural characteristics of the component.

The order of execution or performance of the operations in examples of the disclosure illustrated and described herein is not essential, unless otherwise specified. That is, the operations may be performed in any order, unless otherwise specified, and examples of the disclosure may include additional or fewer operations than those disclosed herein. For example, it is contemplated that executing or performing a particular operation before, contemporaneously with, or after another operation is within the scope of aspects of the disclosure.

It is noted that the terms “substantially” and “about” and “approximately” may be utilized herein to represent the inherent degree of uncertainty that may be attributed to any quantitative comparison, value, measurement, or other representation. These terms are also utilized herein to represent the degree by which a quantitative representation may vary from a stated reference without resulting in a change in the basic function of the subject matter at issue.

While particular embodiments have been illustrated and described herein, it should be understood that various other changes and modifications may be made without departing from the spirit and scope of the claimed subject matter. Moreover, although various aspects of the claimed subject matter have been described herein, such aspects need not be utilized in combination. It is therefore intended that the appended claims cover all such changes and modifications that are within the scope of the claimed subject matter.

What is claimed is:

1. A system for providing a design with consumer feedback, the system comprising:
one or more processors and a non-transitory, computer-readable medium storing instructions that, when executed by the one or more processors, causes the one or more processors to:
receive the design within a design environment, wherein the design comprises a plurality of attributes;
automatically generate, using a model, consumer-based feedback regarding at least one attribute of the plurality of attributes; and
present the consumer-based feedback within the design environment in real-time.

2. The system of claim 1, further comprising instructions to:
receive one or more alternative designs; and
receive, from each consumer within a target consumer demographic, a selection among a plurality of selectable designs.

3. The system of claim 1, further comprising instructions to create the design using design tools comprising computer aided design (CAD) or text descriptions.

4. The system of claim 1, further comprising instructions to use a consumer-in-the-loop approach to receive consumer-based feedback regarding the at least one attribute.

5. The system of claim 4, further comprising instructions to:
compose a well-posed design query to evaluate the model via crowdsourcing a design query over a quantity M of consumers in a target demographic, wherein resulting data may be used to train the model; and
gather statistics pertaining to M responses regarding consumer design preference.

6. The system of claim 1, further comprising instructions to use a model-in-the-loop approach to receive consumer-based feedback regarding the at least one attribute.

7. The system of claim 6, further comprising instructions to:
compose a well-posed design query to evaluate the model over a quantity M of random samples in a target demographic, wherein the model is learned over all consumers in a set; and
gather statistics pertaining to M generated responses regarding consumer design preference.

8. The system of claim 1, wherein the model is generated based upon a well-posed design query crowdsourced among a subset of people in a target demographic.

9. The system of claim 8, wherein the model is further generated utilizing a parametric model or a consumer preference cost function.

10. The system of claim 9, wherein the model is further generated utilizing active learning to generate synthetic queries whose synthetic results are stored in a database and used to further train the model.

11. The system of claim 8, wherein the model is further generated utilizing a nonparametric model.

12. The system of claim 11, wherein the model is further generated utilizing Bayesian optimization to generate synthetic queries whose synthetic results are stored in a database and used to further train the model.

13. A method comprising:
receiving a design within a design environment, wherein the design comprises a plurality of attributes;
automatically generating, using a model, consumer-based feedback regarding at least one attribute of the plurality of attributes; and
presenting the consumer-based feedback within the design environment in real-time.

14. The method of claim 13, further comprising.
receiving one or more alternative designs; and
receiving, from each consumer within a target consumer demographic, a selection among a plurality of selectable designs.

15. The method of claim 13, further comprising:
using a consumer-in-the-loop approach to receive consumer-based feedback regarding the at least one attribute, wherein the consumer-based feedback further comprises: a selection, received from each consumer within a target consumer demographic, regarding a plurality of selectable designs;
composing a well-posed design query to evaluate the model over a quantity M of random samples in a target demographic, Wherein the model is learned over all consumers in a set; and
gathering statistics pertaining, to M generated responses regarding consumer design preference.

16. The method of claim 13, further comprising:
using a model-in-the-loop approach to receive consumer-based feedback regarding the at least one attribute;
composing a well-posed design query to evaluate the model via crowdsourcing a design query over a quantity M of consumers in a target demographic, wherein the model is learned over all consumers in a set; and
gathering statistics pertaining, to M generated responses regarding consumer design preference.

17. The method of claim 13, wherein the model is generated based upon a well-posed design query crowdsourced among a subset of people in a target demographic.

18. The method of claim 17, wherein the model is further generated utilizing a parametric model or a consumer preference cost function.

19. The method of claim 18, wherein the model is further generated utilizing active learning to generate synthetic queries whose synthetic results are stored in a database and used to further train the model.

20. The method of claim 17, wherein the model is further generated utilizing a nonparametric model and Bayesian optimization to generate synthetic queries whose synthetic results are stored in a database and used to further train the model.
